(19) United States
(12) Patent Application Publication
(10) Pub. No.: US 2015/0022205 A1
(43) Pub. Date: Jan. 22, 2015

(54) Automatic Local Coil Isocentering

(71) Applicants: Dominik Paul, Bubenreuth (DE); Raphael Schwarz, Erlangen (DE)

(72) Inventors: Dominik Paul, Bubenreuth (DE); Raphael Schwarz, Erlangen (DE)

(21) Appl. No.: 14/331,719

(22) Filed: Jul. 15, 2014

(30) Foreign Application Priority Data
Jul. 16, 2013 (DE) 102013213907.1

(51) Int. Cl. G01R 33/34; G01R 33/30

(52) U.S. Cl. CPC G01R 33/34084; G01R 33/30
USPC 324/309; 324/321; 324/322

(57) ABSTRACT

A magnetic resonance imaging system includes a control unit configured to (a) compare a plurality of magnitudes of a field of a coil of a local coil, wherein each magnitude of the plurality of magnitudes is measured at a different time; and (b) determine, based on on a comparison result, whether to stop or advance a position adjustment apparatus of the patient couch of the magnetic resonance imaging system.

### RELATED APPLICATIONS

This application claims the benefit of German Patent Application No. DE 102013213907.1, filed Jul. 16, 2013. The entire contents of the priority document are hereby incorporated herein by reference.

### TECHNICAL FIELD

The present teachings relate generally to methods and devices for positioning a local coil in a magnetic resonance imaging (MRI) system.

### BACKGROUND

Magnetic resonance imaging devices (MRIs) for examining objects or patients by magnetic resonance imaging are described, for example, in DE 103 14 215 B4.

### SUMMARY AND DESCRIPTION

The scope of the present invention is defined solely by the appended claims, and is not affected to any degree by the statements within this summary.

In some embodiments, a procedure to optimize a positioning of a local coil in an MRI device is provided.

### BRIEF DESCRIPTION OF THE DRAWINGS

FIG. 1 shows an example of a flowchart for exemplary MRI isocentering with z² coils.

FIG. 2 shows schematically an example of a z¹ field and z¹ coils.

FIG. 3 shows schematically an example of a z² field and z² coils.

FIG. 4 shows schematically an example of a MRI system.

### DETAILED DESCRIPTION

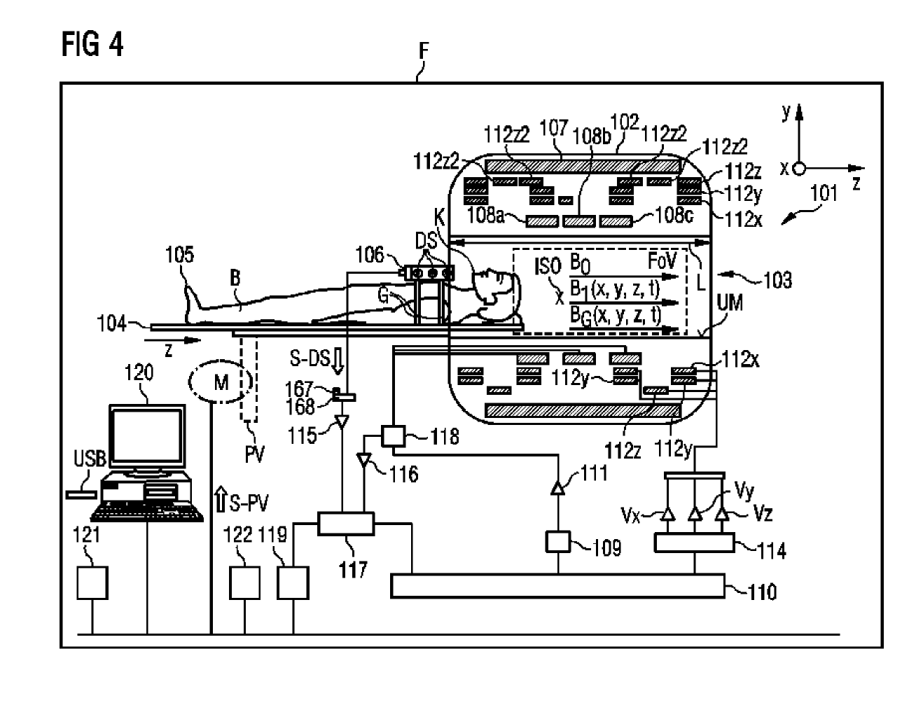

FIG. 4 shows a magnetic resonance imaging (MRI) scanner 101 in a shielded room or Faraday cage F. The scanner 101 includes a whole body coil 102 that, in some embodiments, includes a tubular space 103. A patient couch 104 with an examination object 105 (e.g., a patient), with or without a local coil arrangement 106, may be displaced in the tubular space 103 in a direction of the arrow z to generate recordings of the patient 105 by an imaging method. In some embodiments, a local coil arrangement 106 is arranged on the patient. Recordings of a portion of the body 105 in a local region of the MRI (also referred to as a field of view or FOV) may be generated by the local coil arrangement. Signals of the local coil arrangement 106 may be evaluated (e.g., converted into images, stored, or displayed) by an evaluation device (168, 115, 117, 119, 120, 121, etc.) of the MRI 101. The evaluation device may be connected to the local coil arrangement 106 by, for example, coaxial cables, a radio link 167, or the like.

In order to use a MRI scanner 101 to examine a body 105 (e.g., an examination object or a patient) by magnetic resonance imaging, different magnetic fields that are matched to one another in temporal and spatial characteristics are radiated onto the body 105. A strong magnet (e.g., a cryomagnet 107) in a measurement cabin with an opening 103 that, in some embodiments, is tunnel-shaped may generate a strong static main magnetic field BO (e.g., having a strength of 0.2 Tesla to 3 Tesla or greater). A body 105 to be examined is supported by a patient couch 104 and driven into a region of the main magnetic field BO that is substantially homogeneous in the observation region field of view (FOV). The nuclear spins of atomic nuclei of the body 105 are excited by magnetic radiofrequency excitation pulses B1 (x, y, z, t) that are radiated by a radiofrequency antenna (and/or, optionally, a local coil arrangement). The radiofrequency antenna is depicted in a greatly simplified manner as a multi-part body coil 108 (e.g., 108a, 108b, 108c). By way of example, radiofrequency excitation pulses are generated by a pulse generation unit 109 that is controlled by a pulse sequence control unit 110. After amplification by a radiofrequency amplifier 111, the radiofrequency excitation pulses are conducted to the radiofrequency antenna 108. The radiofrequency system is shown schematically in FIG. 4. In a magnetic resonance imaging scanner 101, more than one pulse generation unit 109, more than one radiofrequency amplifier 111, and more than one radiofrequency antenna 108a, 108b, 108c may be used.

The magnetic resonance imaging scanner 101 further includes gradient coils 112x, 112y, 112z. Magnetic gradient fields BG (x, y, z, t) are radiated by the gradient coils during a measurement for selective slice excitation and for spatial encoding of the measurement signal. The gradient coils 112x, 112y, 112z are controlled by a gradient coil control unit 114 (and, optionally, via amplifiers Vx, Vy, Vz). The gradient coil control unit 114, like the pulse generation unit 109, is connected to the pulse sequence control unit 110.

Signals emitted by the excited nuclear spins (e.g., of the atomic nuclei in the examination object) are received by the body coil 108 and/or at least one local coil arrangement 106. The signals are amplified by associated radiofrequency preamplifiers 116 and further processed and digitized by a reception unit 117. The recorded measurement data are digitized and stored as complex numbers in a k-space matrix. An associated MRI image may be reconstructed from the k-space matrix filled with values by a multidimensional Fourier transform.

For a coil that may be operated in both transmission mode and in reception mode (e.g., the body coil 108 or a local coil 106), the correct signal transmission is regulated by an upstream transmission/reception switch 118.

An image-processing unit 119 generates an image from the measurement data that is displayed to a user by an operating console 120 and/or stored in a storage unit 121. A central computer unit 122 controls the individual installation components.

In MR imaging, images with a high signal-to-noise ratio (SNR) may be recorded using local coil arrangements (e.g., coils, local coils). Local coil arrangements are antenna systems that are attached in the direct vicinity on (anterior) or under (posterior), or at or in, the body 105. During an MR measurement, the excited nuclei induce a voltage in the individual antennae of the local coil. The voltage is then amplified using a low-noise preamplifier (e.g., LNA, preamp) and transmitted to the reception electronics. In order to improve the signal-to-noise ratio even for high-resolution images, high-field installations (e.g., 1.5 Tesla to 12 Tesla or greater) may be used. If more individual antennae are connected to an MR reception system than there are receivers available, a switching matrix (also referred to as RCCS) may be installed between the reception antennae and receivers. The matrix routes the currently active reception channels (e.g., the channels that currently lie in the field of view of the magnet) to the available receivers. As a result, more coil elements may be connected than there are receivers available because, in the case of a whole body cover, only coils that are situated in the FOV or in the homogeneous volume of the magnet are read.

By way of example, an antenna system that may include one antenna element or, as an array coil, several antenna elements (e.g., coil elements) may be referred to as a local coil arrangement 106. In some embodiments, these individual antenna elements may be embodied as loop antennae (loops), butterfly coils, flex coils, or saddle coils. In some embodiments, a local coil arrangement includes coil elements, a preamplifier, additional electronics (e.g., standing wave traps, etc.), a housing, and supports. The local coil arrangement may also include a cable with a plug for connecting to the MRI scanner. A receiver 168 attached to the scanner side filters and digitizes a signal received from a local coil 106 (e.g., by radio link, etc.) and transmits the data to a digital signal-processing device. The digital signal-processing device may derive an image or spectrum from the data obtained by a measurement and makes the image or spectrum available to the user (e.g., for subsequent diagnosis by the user and/or for storing).

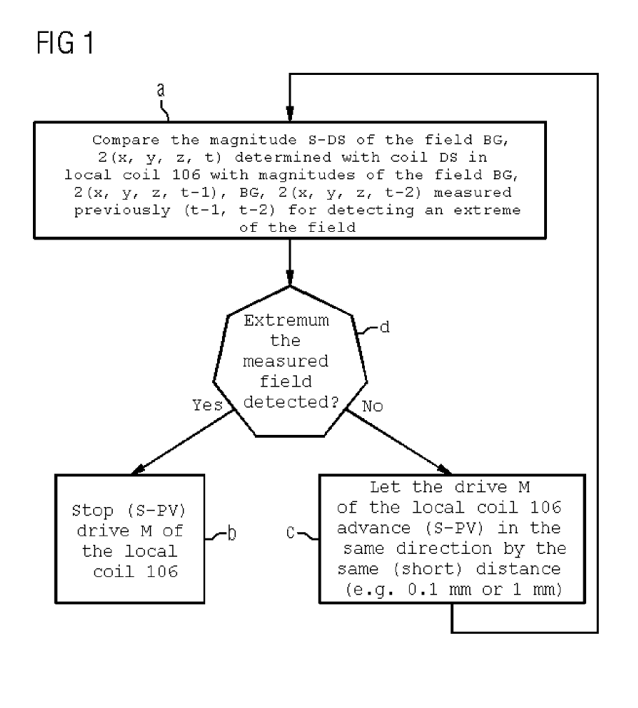

FIG. 1 shows a flowchart outlining an exemplary process for determining the position of and isocentering the MRI with, for example, z² coils (e.g., z² gradient coils and/or z² shim coils).

A magnitude of a current (t) field (e.g., a second-order gradient field BG, 2(x, y, z, t) or an RF field B1 or a measured sum of all currently existing fields B0, B1, BG, BG2), measured in a local coil 106 using one or more coils DS (also referred to as antennae) is transmitted as a signal S-DS to a control unit 120 of the MRI 101 (e.g., every 0.1 seconds or every 0.01 seconds, at times t−2, t−1, t, etc.). The control unit 120 compares the magnitude of the current (t) field BG, 2(x, y, z, t) with, for example, two or more magnitudes of the field (BG, 2(x, y, z, t−1), BG, 2(x, y, z, t−2)) measured at earlier times (t−1, t−2). The control unit 120 determines whether there is an extremum of the field BG, 2(x, y, z, t) at a given time compared with the field at the times (t−1, t−2) therebefore and/or thereafter (e.g., by detecting a maximum or a minimum or a zero crossing of the first derivative of the magnitude of the field).

If the control unit 120 determines that there is no extremum of the measured field in the local coil, the control unit 120 advances the patient couch 104 (and the local coil 106 thereon) closer to the isocenter ISO of the MRI. The control unit 120 may advance the patient couch 104, for example, by sending a signal S-PV to a drive M of the position adjustment apparatus PV of the patient couch 104.

If the control unit 120 determines that there is an extremum of the measured field in the local coil, the control unit 120 stops the patient couch 104 (and the local coil 106 situated thereon) because the local coil is already sufficiently close to the isocenter ISO of the MRI. The control unit 120 may stop the patient couch 104, for example, by sending a signal S-PV to a drive M of the position adjustment apparatus PV of the patient couch 104.

Optionally, the patient couch 104 (and the local coil 106 situated thereon) may be slightly retracted as a result of a signal S-PV to a drive M of the position adjustment apparatus PV of the patient couch 104. For example, the patient couch 104 (and the local coil 106 situated thereon) may be slightly retracted in this manner if the local coil has already passed through the isocenter ISO because the extremum of the field is only detected after the isocenter.

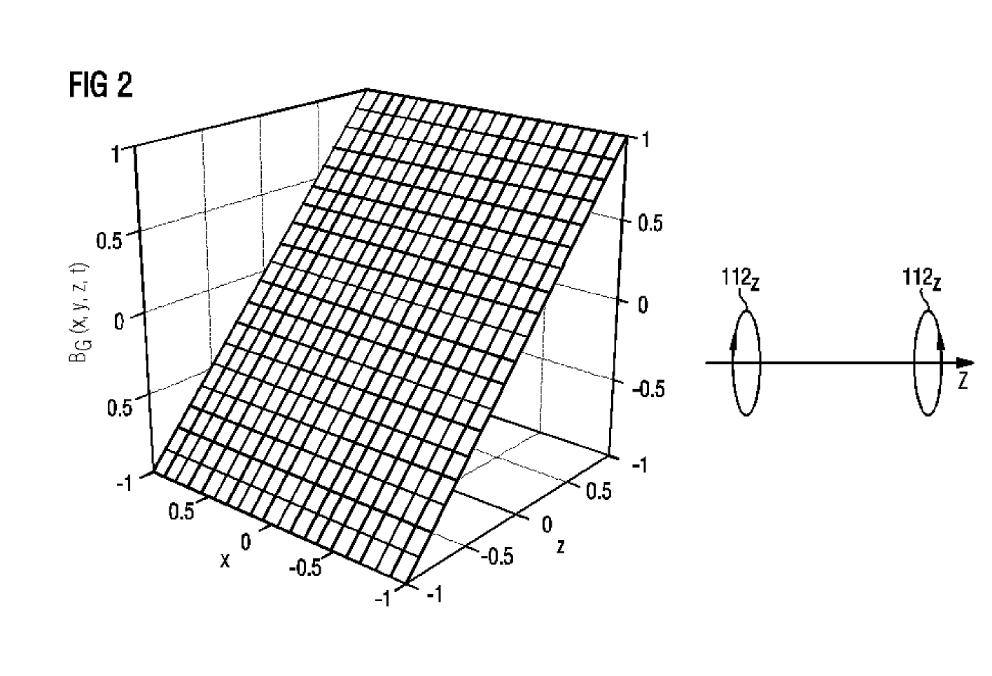

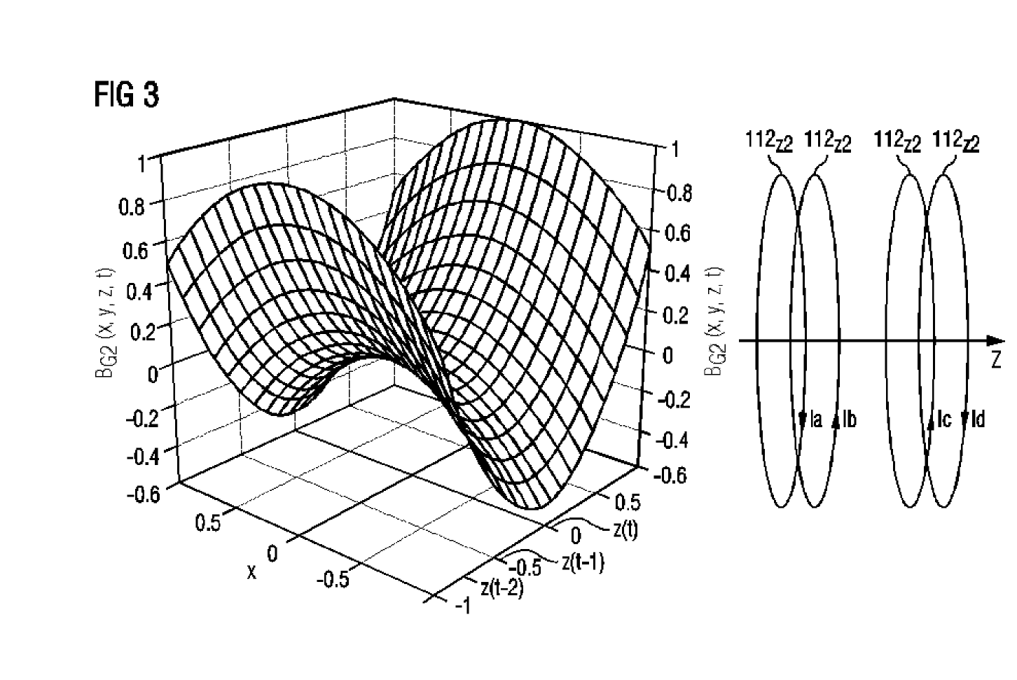

The search of an extremum may be facilitated by z² gradient coils 112_{z2} and/or z² shim coils of the MRI 101, as shown in FIGS. 2 and 3.

FIG. 2 shows a schematic illustration of imaging by z-gradient coils 112z (also referred to as z1 gradient coils) and/or z-shim coils (e.g., optionally configured and/or arranged similarly to gradient coils). In some embodiments, z-gradient coils may be used for z-shimming. As shown on the left-hand side of FIG. 2, a first-order (gradient) magnetic field B_{G}(x, y, z, t) that increases approximately linearly in the z-direction (e.g., as a result of current propagating in opposite directions in the two gradient coils, as shown by the arrows) is generated in an MRI 101 for selective slice excitation and for spatial encoding of measurement signals (B1).

FIG. 3 shows a schematic illustration of imaging by z²-gradient coils 112_{z2} and/or z²-shim coils (e.g., optionally configured and/or arranged similarly to z²-gradient coils). In some embodiments, z²-gradient coils may be used for z-shimming. As shown on the right-hand side of FIG. 3, a magnetic field B_{G}(x, y, z, t) that is approximately quadratic and/or parabolic and/or that (e.g., in a slice in z, y-planes) decreases (e.g., up to z=0) and then increases (e.g., from z=0) in the z-direction (e.g., as a result of currents propagating in opposite directions in two adjacent coils of the four coils 112_{z2}, as shown by the arrows, and further as a result of currents propagating mirror symmetrically in the two pairs of z² coils, as shown on the left-hand side of FIG. 3) is generated in an MRI 101. The magnetic field B_{G}(x, y, z, t) may be generated in the MRI 101 for selective slice excitation, for spatial encoding of the measurement signal, and/or for z² shimming. The magnetic field B_{G}(x, y, z, t) may optionally be superposed on other fields, such as a shim field and/or z1-gradient field of the coils 112z and/or the B0-field of the main field magnet and/or the RF field of the RF coils 108a, 108b, 108c, etc. See, for example, “Second Order Shimming of High Field Magnets” by Siemens Medical.

Hence, MRI isocentering may be used as an alternative to other methods (e.g., laser measuring, etc.). The MRI isocentering includes moving the center of the local coil 106 toward the center of the main field magnet and/or the center of the FOV of the MRI along one or two or three of the axes x, y, z (e.g., in the z-direction with z² coils).

If a local coil 106 is arranged on a region of a patient 105 (e.g., on the patient's head K, leg B, thorax, or the like) that is to be examined by the MRI 101 (in other words, an “anatomical region of interest”), the local coil 106 may be displaced into the isocenter ISO (indicated by “x”) of the main field magnet 107 and/or the isocenter of the field of view (e.g., MRI image recording region) of the MRI 101 by displacing a patient couch 104 that the local coil lies upon (e.g., either loosely without being fastened to the patient couch 104 or, in other embodiments, fastened to the patient couch 104). The patient couch 104 may be displaced by a motor M and a position adjustment apparatus PV. The motor M is shown schematically in FIG. 4 and may be actuated by a control unit 120 and pulse sequence control unit 110.

A field generated by z-shim coils may be used. For example, the z-squared coils (e.g., the z2 gradient coils 112_{z2}) may be used when there is a displacement of the patient table 104 (and, therefore, of the local coil 106 situated on the patient table 104) along an axis (e.g., the z-axis) through the center of the bore 103 of the local coil 106 in order to determine when the isocenter (e.g., the center) of the main field magnet 107 and/or the isocenter of the field of view (e.g., MRI image recording region) of the MRI 101 has been passed through. The z-squared coils (e.g., the z2 gradient coils 112_{z2}) may be used in order to stop the local coil 106 at or near the isocenter point (e.g., by stopping the drive M of the position adjustment apparatus PV of the patient couch 104 that the local coil 106 is situated on).

The patient table 104 and the local coil 106 situated on the patient table 104 may be displaced by the drive M of the position adjustment apparatus PV in such a way that, for example, the patient couch 104 is displaced over the entire available length of an axis (e.g., “z”) until the isocenter ISO has been reached because the quadratic (e.g., =“z2”) field (B_{G,2}(x, y, z, t)) detected in one/several coils DS in the local coil 106 passes through an extremum during the movement (e.g., increases to a maximum and then decreases after ISO, reduces to a minimum and then increases after ISO, or has a first derivative of zero). Alternatively, the patient table 104 and the local coil 106 situated on the patient table 104 may be displaced by the drive M of the position adjustment apparatus PV in such a way that, for example, the increase or decrease of the quadratic (e.g., =“z2”) field (B_{G,2}(x, y, z, t)) detected in the coils DS of the local coil 106 is registered and used to determine the direction of the local coil 106 containing the isocenter ISO. There may be a reversal of direction in the case of a displacement in a direction that is counter to the isocenter ISO. The searching is continued until an extremum in the quadratic (e.g., =“z2”) field (B_{G,2}(x, y, z, t)) detected in the coils DS of the local coil 106 is found, thereby expediting locating the isocenter.

The quadratic (e.g., =“z2”) field (B_{G,2}(x, y, z, t)) detected in the coils DS of the local coil 106 may be determined to the extent that the magnitude thereof is measured and/or that a time phase (e.g., of an RF signal) is determined.

The coils DS in the local coil 106 used to measure (e.g., detect) the quadratic (e.g., =“z2”) field (B_{G,2}(x, y, z, t)) may be any coils in the local coil. For example, RF coils in the local coil may be used for MRI imaging. Alternatively, shim coils or the like may be used in the local coil.

The evaluating of the field—for example, the quadratic (e.g., =“z2”) field in the z-direction (B_{G,2}(x, y, z, t))) detected with the coils DS of the local coil 106 may be carried out in the control unit 120 and/or the pulse sequence control unit 110 of the MRI. In addition, the actuating of the drive M of the position adjustment apparatus PV of the patient couch 104, and the determining of the isoposition being reached by the local coil 106 (e.g., due to an extremum of the field (B_{G,2}(x, y, z, t)) detected in the local coil) may be carried out in the control unit 120 and/or the pulse sequence control unit 110 of the MRI.

In accordance with the present teachings, manual or automatic positioning by, for example, light markers on the patient and the use of lasers may be avoided. Good workflows and low susceptibilities to errors may be observed.

Methods and devices in accordance with the present teachings may be applied, for example, with a local coil 106 placed on a patient couch (e.g., a knee coil, a hip coil, a shoulder coil, a foot coil, an ankle coil, a wrist coil, a head coil, a chest coil, or the like).

While the present invention has been described above by reference to various embodiments, it should be understood that many changes and modifications may be made to the described embodiments. It is therefore intended that the foregoing description be regarded as illustrative rather than limiting, and that it be understood that all equivalents and/or combinations of embodiments are intended to be included in this description.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding claim—whether independent or dependent—and that such new combinations are to be understood as forming a part of the present specification.

1. A magnetic resonance imaging system comprising a control unit and a patient couch, wherein the control unit is configured to (a) compare a plurality of magnitudes of a field of a coil of a local coil, wherein each magnitude of the plurality of magnitudes is measured at a different time; and (b) determine, based on a comparison result, whether to stop or advance a position adjustment apparatus of the patient couch of the magnetic resonance imaging system.

2. The magnetic resonance imaging system of claim 1, wherein the control unit is further configured to (c) determine whether there is an extremum of a magnitude of the field compared with at least one magnitude of the field measured at an earlier time; and (d) stop the position adjustment apparatus of the patient couch if it is determined that the extremum is present, or advance the position adjustment apparatus of the patient couch if it is determined that the extremum is not present.

3. The magnetic resonance imaging system of claim 1, further comprising four coils, wherein the magnetic resonance imaging system is configured to apply current in opposite directions in adjacent coils, and wherein the four coils are configured to generate one or more of a quadratic field, a second-order shim field, a second-order gradient field, and a field having a substantially quadratic profile in terms of one or more of a magnitude along a z axis in the magnetic resonance imaging system, a z2 gradient field, and a z2 shim field.

4. The magnetic resonance imaging of claim 1, further comprising at least four coils, wherein each of the at least four coils is configured for an application therein of a current, wherein a current applied in a first coil is in an opposite direction to a current applied in an adjacent second coil, and wherein the at least four coils extend about a longitudinal axis of a bore of the magnetic resonance imaging system.

5. The magnetic resonance imaging system of claim 1, further comprising at least four coils, wherein two of the at least four coils are arranged at a first end of a bore of the magnetic resonance imaging system, wherein each of the two coils is configured for an application therein of a current, and wherein a current applied in a first of the two coils is in an opposite direction to a current applied in the other of the two coils.

6. The magnetic resonance imaging system of claim 1, wherein the control unit is further configured to move the position adjustment apparatus of the patient couch until a local coil lying on the patient couch is situated in an isocenter of a main field magnet of the magnetic resonance imaging system.

7. The magnetic resonance imaging system of claim 1, further comprising a local coil comprising a coil configured to determine at least a magnitude of a magnetic field at a plurality of times, and to communicate at least one analog or digital signal to the control unit of the magnetic resonance imaging system.

8. A method for moving a local coil on a patient couch of a magnetic resonance imaging system to an isocenter of the magnetic resonance imaging system, the magnetic resonance imaging system comprising a control unit, the method comprising:
comparing a plurality of magnitudes of a field using the control unit, wherein each magnitude of the plurality of magnitudes is measured by at least one coil of the local coil at a different time; and
stopping or advancing a position adjustment apparatus of the patient couch based on a result of the comparing.

9. The method of claim 8, further comprising:
determining whether there is an extremum of a magnitude of the field of the coil of the local coil compared to at least one magnitude of the field measured at an earlier time;
stopping the position adjustment apparatus of the patient couch if it is determined that the extremum is present; and
advancing the position adjustment apparatus of the patient couch if it is determined that the extremum is not present.

10. The method of claim 8, wherein the magnetic resonance imaging system further comprises four coils, the method further comprising:
applying, by the magnetic resonance imaging system, a current in opposite directions in adjacent coils of the four coils;
generating one or more of a quadratic field, a second-order shim field, a second-order gradient field, and a field having a substantially quadratic profile in terms of one or more of a magnitude along a z axis in the magnetic resonance imaging system, a z2 gradient field, and a z2 shim field.

11. The method of claim 8, wherein the magnetic resonance imaging system further comprises at least four coils, the method further comprising:
applying a current in opposite directions in adjacent coils of the at least four coils, wherein the at least four coils extend about a longitudinal axis of a bore of the magnetic resonance imaging system.

12. The method of claim 8, wherein the magnetic resonance imaging system further comprises at least four coils, wherein two of the at least four coils are arranged at a first end of a bore of the magnetic resonance imaging system, the method further comprising applying a current in opposite directions in the two of the at least four coils.

13. The method of claim 8, further comprising advancing the position adjustment apparatus of the patient couch until a local coil lying on the patient couch is situated in an isocenter of the magnetic resonance imaging system.

14. The method of claim 8, wherein the magnetic resonance imaging system further comprises a local coil, the local coil comprising a coil, the method further comprising:
determining a magnitude of a magnetic field with the coil; and
communicating an analog or a digital signal to the control unit of the magnetic resonance imaging system.

15. A computer program product comprising a non-transitory computer-readable storage medium configured to be loaded into a magnetic resonance imaging system, the computer-readable storage medium comprising instructions executable by a programmable control unit of the magnetic resonance imaging system, the computer-readable storage medium comprising instructions for:
comparing a plurality of magnitudes of a field using the control unit, wherein each magnitude of the plurality of magnitudes is measured by at least one coil of the local coil at a different time; and
stopping or advancing a position adjustment apparatus of the patient couch based on a result of the comparing.

16. A non-transitory electronically-readable data medium having stored therein data representing instructions executable by a programmable control unit of a magnetic resonance imaging system, the data medium comprising instructions for:
comparing a plurality of magnitudes of a field using the control unit, wherein each magnitude of the plurality of magnitudes is measured by at least one coil of the local coil at a different time; and
stopping or advancing a position adjustment apparatus of the patient couch based on a result of the comparing.

17. The magnetic resonance imaging system of claim 2, further comprising four coils, wherein the magnetic resonance imaging system is configured to apply current in opposite directions in adjacent coils, and wherein the four coils are configured to generate one or more of a quadratic field, a second-order shim field, a second-order gradient field, and a field having a substantially quadratic profile in terms of one or more of a magnitude along a z axis in the magnetic resonance imaging system, a z2 gradient field, and a z2 shim field.

18. The magnetic resonance imaging of claim 2, further comprising at least four coils, wherein each of the at least four coils is configured for an application therein of a current, wherein a current applied in a first coil is in an opposite direction to a current applied in an adjacent second coil, and wherein the at least four coils extend about a longitudinal axis of a bore of the magnetic resonance imaging system.

19. The magnetic resonance imaging of claim 3, further comprising at least four coils, wherein each of the at least four coils is configured for an application therein of a current, wherein a current applied in a first coil is in an opposite direction to a current applied in an adjacent second coil, and wherein the at least four coils extend about a longitudinal axis of a bore of the magnetic resonance imaging system.

20. The magnetic resonance imaging system of claim 2, further comprising at least four coils, wherein two of the at least four coils are arranged at a first end of a bore of the magnetic resonance imaging system, wherein each of the two coils is configured for an application therein of a current, and wherein a current applied in a first of the two coils is in an opposite direction to a current applied in the other of the two coils.
